(19) United States
(12) Patent Application Publication
(10) Pub. No.: US 2014/0184433 A1
(43) Pub. Date: Jul. 3, 2014

(54) DELTA-SIGMA MODULATION APPARATUS AND DYNAMIC ELEMENT-MATCHING CIRCUIT THEREOF

(71) Applicants: QUADLINK TECHNOLOGY,INC., Hsinchu County (TW); QUADLINK TECHNOLOGY, INC., Shanghai (CN)

(72) Inventor: Jian-Qiu Chen, Shanghai (CN)

(73) Assignees: QUADLINK TECHNOLOGY, INC., Shanghai (CN); QUADLINK TECHNOLOGY, INC., Hsinchu County (TW)

(21) Appl. No.: 13/794,813

(22) Filed: Mar. 12, 2013

(30) Foreign Application Priority Data
Dec. 28, 2012 (CN) 201210583817.7

(51) Int. Cl. H03M 1/06

(52) U.S. Cl. CPC H03M 1/0617
USPC 341/144

(57) ABSTRACT

A delta-sigma modulation apparatus and a dynamic element-matching circuit thereof are disclosed. The dynamic element-matching circuit includes a data aligner, a logic operation circuit, and a delayer. The data aligner receives an input matching data and a pointer signal and shifts the input matching data according to the pointer signal to generate an output matching data. The logic operation circuit receives the output matching data and performs a logic operation on the output matching data to generate a preceding pointer signal. The delayer receives the preceding pointer signal and delays the preceding pointer signal according to a sample clock pulse to generate the pointer signal.

### CROSS-REFERENCE TO RELATED APPLICATION

This application claims the priority benefit of China application serial no. 201210583817.7, filed on Dec. 28, 2012. The entirety of the above-mentioned patent application is hereby incorporated by reference herein and made a part of this specification.

### BACKGROUND OF THE INVENTION

1. Field of the Invention

The invention generally relates to a delta-sigma modulation apparatus, and more particularly, to a delta-sigma modulation apparatus and a dynamic element-matching circuit thereof.

2. Description of Related Art

The dynamic element-matching circuit in an existing multi-digit delta-sigma modulation apparatus has to be designed to overcome the non-linear characteristic of a digital-to-analog converter (DAC) in the delta-sigma modulation apparatus. In a high-speed data transmission application, the working frequency of a delta-sigma modulation apparatus is usually limited by the operation time of a dynamic element-matching circuit.

FIG. 1 is a block diagram of a conventional dynamic element-matching circuit 100. Referring to FIG. 1, the dynamic element-matching circuit 100 includes an adder 110, a delayer 120, and a logic circuit 130. The adder 110 receives an input matching data DIN and performs an addition operation on the input matching data DIN and an output of the delayer 120. The adder 110 outputs addition result to the delayer 120 and the logic circuit 130. After the delayer 120 receives the addition result from the adder 110, the delayer 120 delays the addition result for a sample clock pulse TS.

Besides, the delayer 120 also outputs the delayed addition result to the logic circuit 130. The logic circuit 130 receives the outputs of the delayer 120 and the adder 110 and performs a logic operation on the consecutive input matching data DIN produced at different time points to generate an output matching data DOUT.

The conventional dynamic element-matching circuit 100 requires a multi-digit adder 110 to perform the addition operation. The adder 110 allows the input matching data DIN to be sent to the logic circuit 130. As a result, the hardware cost of the dynamic element-matching circuit 100 is increased.

### SUMMARY OF THE INVENTION

Accordingly, the invention is directed to a delta-sigma modulation apparatus and a dynamic element-matching circuit thereof, in which the circuit area, and accordingly the hardware cost, is effectively reduced.

The invention provides a dynamic element-matching circuit including a data aligner, a logic operation circuit, and a delayer. The data aligner receives an input matching data and a pointer signal and shifts the input matching data according to the pointer signal to generate an output matching data. The logic operation circuit is coupled to the data aligner. The logic operation circuit receives the output matching data and performs a logic operation on the output matching data to generate a preceding pointer signal. The delayer is coupled to the logic operation circuit and the data aligner. The delayer receives the preceding pointer signal and delays the preceding pointer signal according to a sample clock pulse to generate the pointer signal.

According to an embodiment of the invention, the logic operation circuit includes N AND gates. The input of the 1^{st} AND gate receives reverse value of the 1^{st} output bit and the N^{th} output bit among the output bits of the output matching data, and the output of the 1^{st} AND gate generates the 1^{st} bit of the preceding pointer signal. The input of the i^{th} AND gate receives reverse value of the i^{th} output bit and the (i−1)^{th} output bit among the output bits of the output matching data, and the output of the i^{th} AND gate generates the i^{th} bit of the preceding pointer signal.

According to an embodiment of the invention, the logic operation circuit includes N NAND gates and N NOT gates. The input of the 1^{st} NAND gate receives reverse value of the 1^{st} output bit and the N^{th} output bit among the output bits of the output matching data, and the input of the i^{th} NAND gate receives reverse value of the i^{th} output bit and the (i−1)^{th} output bit among the output bits of the output matching data. The inputs of the NOT gates are respectively coupled to the outputs of the NAND gates, and the outputs of the NOT gates generate the preceding pointer signal.

According to an embodiment of the invention, the data aligner is a lookup table. The lookup table records a corresponding relationship among the input matching data, the pointer signal, and the output matching data.

According to an embodiment of the invention, the delayer is a latch. The latch latches the preceding pointer signal according to the sample clock pulse and provides the latched preceding pointer signal as the pointer signal according to the sample clock pulse.

The invention provides a delta-sigma modulation apparatus including an arithmetic unit, a filter, an analog-to-digital converter (ADC), a digital-to-analog converter (DAC), and a dynamic element-matching circuit. The arithmetic unit receives an analog input signal and an output of the DAC and performs an arithmetic operation on the analog input signal and the output of the DAC to generate an operation result. The filter receives the operation result from the arithmetic unit and amplifies and filters the operation result. The ADC coupled to the filter performs an analog-to-digital conversion operation on the operation result to generate an output data. The dynamic element-matching circuit receives the output data and performs a dynamic element-matching alignment on the output data. The DAC receives the output of the dynamic element-matching circuit and performs a digital-to-analog conversion operation. The dynamic element-matching circuit includes a data aligner, a logic operation circuit, and a delayer. The data aligner receives an input matching data and a pointer signal and shifts the input matching data according to the pointer signal to generate an output matching data. The logic operation circuit is coupled to the data aligner. The logic operation circuit receives the output matching data and performs a logic operation on the output matching data to generate a preceding pointer signal. The delayer is coupled to the logic operation circuit and the data aligner. The delayer receives the preceding pointer signal and delays the preceding pointer signal according to a sample clock pulse to generate the pointer signal.

As described above, in the invention, a logic operation circuit receives an output signal generated by a data aligner and generates a pointer signal, and the data aligner generates a new output signal according to the pointer signal and an input signal. Thus, no adder is needed in the data aligner. Accordingly, the power consumption and layout area of the circuit are effectively reduced, the hardware cost and power consumption of a delta-sigma modulation apparatus are also effectively reduced.

These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram of a conventional dynamic element-matching circuit 100.

FIG. 2 is a diagram of a dynamic element-matching circuit 200 according to an embodiment of the invention.

FIG. 3A and FIG. 3B are diagrams respectively illustrating different implementations of a logic operation circuit 220 according to embodiments of the invention.

FIG. 4 is a diagram illustrating an implementation of a delayer 230 according to an embodiment of the invention.

FIG. 5 is a diagram illustrating an implementation of a data aligner 210 according to an embodiment of the invention.

FIG. 6 is a diagram of a delta-sigma modulation apparatus 600 according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

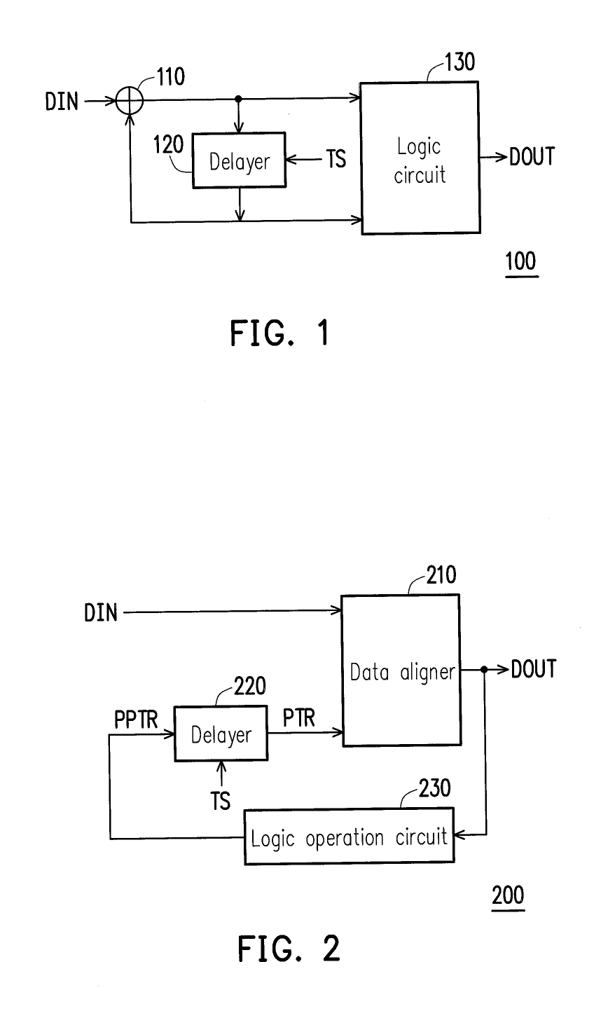

FIG. 2 is a diagram of a dynamic element-matching circuit 200 according to an embodiment of the invention. Referring to FIG. 2, the dynamic element-matching circuit 200 includes a data aligner 210, a logic operation circuit 220, and a delayer 230. The data aligner 210 receives an input matching data DIN and a pointer signal PTR and shifts the input matching data DIN according to the pointer signal PTR to generate an output matching data DOUT. The logic operation circuit 220 is coupled to the data aligner 210. The logic operation circuit 220 receives the output matching data DOUT and performs a logic operation on the output matching data DOUT to generate a preceding pointer signal PPTR.

The delayer 230 is coupled to the logic operation circuit 220 and the data aligner 210. The delayer 230 receives a sample clock pulse TS and delays the preceding pointer signal PPTR generated by the logic operation circuit 220 according to the sample clock pulse TS to generate the pointer signal PTR. To be specific, the delayer 230 delays the preceding pointer signal PPTR by a cycle of the sample clock pulse TS to generate the pointer signal PTR.

It should be noted that in the present embodiment, the data aligner 210 directly receives the input matching data DIN and shifts the input matching data DIN according to the pointer signal PTR to generate the output matching data DOUT. In other words, no adder is disposed on the path for the data aligner 210 to receive the input matching data DIN. Accordingly, the input matching data DIN can be quickly sent into the data aligner 210, and accordingly the processing rate of the dynamic element-matching circuit 200 can be increased.

In addition, the logic operation circuit 220 is a logic circuit without any adder. The logic operation circuit 220 directly receives the output matching data DOUT from the data aligner 210 and performs a logic operation on the output matching data DOUT to generate the preceding pointer signal PPTR. In the present embodiment, the logic operation circuit 220 generates the preceding pointer signal PPTR according to the transition state of the output matching data DOUT. For example, when the 1^{st} to the 6^{th} output bits of the output matching data DOUT respectively have the binary values 001100, the 2^{nd} to the 3^{rd} output bits of the output matching data DOUTtransit from 0 to 1. Accordingly, the 3^{rd} bit of the preceding pointer signal PPTR generated by the logic operation circuit 220 is 1, while the other bits of the preceding pointer signal PPTR are all 0. If the 1^{st} to the 6^{th} output bits of the output matching data DOUT respectively have the binary values 000011, the 4^{th} to the 5^{th} output bits of the output matching data DOUT transit from 0 to 1. Accordingly, the 5^{th} bit of the preceding pointer signal PPTR generated by the logic operation circuit 220 is 1, while the other bits of the preceding pointer signal PPTR are all 0.

To be specific, assuming that the output matching data DOUT is a logic signal having N output bits (N is a positive integer greater than 1), the logic operation circuit 220 performs an AND operation on the reverse value of the 1^{st} output bit and the N^{th} output bit among the output bits of the output matching data DOUT to generate the 1^{st} bit of the preceding pointer signal PPTR. The logic operation circuit 220 also performs an AND operation on the reverse value of the i^{th} output bit and the (i+1)th output bit among the output bits of the output matching data DOUT to generate the i^{th} bit of the preceding pointer signal PPTR. Herein N is a positive integer greater than 1, and i is a positive integer greater than 1 and smaller than N.

The logic operation circuit 220 performs a logic operation on the output matching data DOUT to generate the preceding pointer signal PPTR, which is different from the technique adopted by a conventional dynamic element-matching circuit in which the preceding pointer signal is generated through an addition operation performed on the input matching data. Thereby, no adder is required by the logic operation circuit 220 in the present embodiment.

The data aligner 210 shifts the input matching data DIN according to the pointer signal PTR to generate the output matching data DOUT. In the present embodiment, the data aligner 210 is a lookup table. The lookup table records a corresponding relationship among the input matching data DIN, the pointer signal PTR, and the output matching data DOUT. Namely, when the data aligner 210 receives the input matching data DIN and the pointer signal PTR, it finds out and outputs the output matching data DOUT according to the corresponding relationship among the input matching data DIN, the pointer signal PTR, and the output matching data DOUT recorded in the lookup table.

It should be noted that in the present embodiment, no adder is required in the dynamic element-matching circuit 200. Namely, the circuit area of the dynamic element-matching circuit 200 is not increased due to any multi-digit adder. Thus, the hardware circuit cost is effectively reduced.

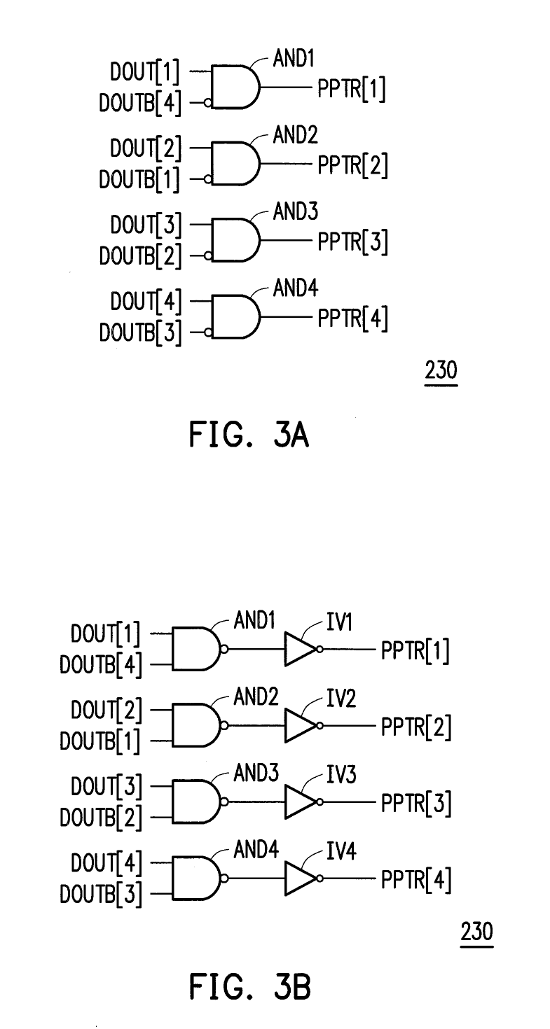

FIG. 3A and FIG. 3B are diagrams respectively illustrating different implementations of the logic operation circuit 220 according to embodiments of the invention. Referring to FIG. 3A, the logic operation circuit 220 includes a plurality of AND gates AND1-AND4. The AND gate AND1 receives the reverse value DOUTB[4] of the 1^{st} output bit DOUT[1] and the N^{th} output bit (N=4) among the output bits of the output matching data DOUT. The AND gate AND2 receives the reverse value DOUTB[1] of the 2^{nd} output bit DOUT[2] and the 1^{st} output bit among the output bits of the output matching data DOUT. The AND gate AND3 receives the reverse value DOUTB[2] of the 3^{rd} output bit DOUT[3] and the 2^{nd} output bit among the output bits of the output matching data DOUT. The AND gate AND4 receives the reverse value DOUTB[3] of the 4^{th} output bit DOUT[4] and the 3^{rd} output bit among the output bits of the output matching data DOUT. The AND gates AND 1-AND4 respectively generate a plurality of bits PPTR[1]-PPTR[4] of the preceding pointer signal PPTR.

Referring to FIG. 3B, the logic operation circuit 220 includes a plurality of NAND gates NA1-NA4 and a plurality of NOT gates IV1-IV4. The inputs of the NOT gates IV1-IV4 are respectively coupled to the outputs of the NAND gates NA1-NA4, and the outputs of the NOT gates IV1-IV4 respectively generate a plurality of bits PPTR[1]-PPTR[4] of the preceding pointer signal PPTR. The NAND gate NA1 receives the reverse value DOUTB[4] of the 1^{st} output bit DOUT[1] and the N^{th} output bit (N=4) among the output bits of the output matching data DOUT. The NAND gate NA2 receives the reverse value DOUTB[1] of the 2^{nd} output bit DOUT[2] and the 1^{st} output bit among the output bits of the output matching data DOUT. The NAND gate NA3 receives the reverse value DOUTB [2] of the 3^{rd} output bit DOUT[3] and the 2^{nd} output bit among the output bits of the output matching data DOUT. The NAND gate NA4 receives the reverse value DOUTB[3] of the 4^{th} output bit DOUT[4] and the 3^{rd} output bit among the output bits of the output matching data DOUT. The NOT gates IV1-IV4 respectively generate a plurality of bits PPTR[1 ]-PPTR[4] of the preceding pointer signal PPTR.

It should be noted that the implementation with 4 AND gates and NAND gates illustrated in FIG. 3A and FIG. 3B is only an example, where the numbers of the AND gates and the NAND gates are corresponding to the number of the output bits of the output matching data DOUT. In addition, the logic operation circuit 220 may also be composed of other logic gates which can generate the same logic operation results, and the technique of achieving the same logic operation results through different logic gates is well known to those having ordinary knowledge in the art therefore will not be described herein.

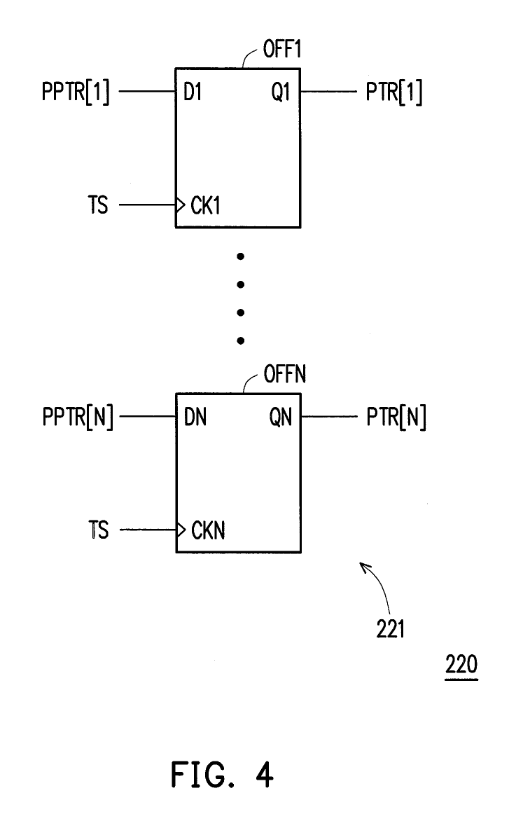

FIG. 4 is a diagram illustrating an implementation of the delayer 230 according to an embodiment of the invention. Referring to FIG. 4, the delayer 230 includes a latch 221. The latch 221 is composed of a plurality of D-type flip-flops OFF1-OFFN. The data terminals D1-DN of the D-type flip-flops OFF1-OFFN respectively receive the bits PPTR[1]-PPTR[N] of the preceding pointer signal PPTR, and the clock pulse terminals CK1-CKN of the D-type flip-flops OFF1-OFFN receive the sample clock pulse TS. In addition, the output terminals Q1-QN of the D-type flip-flops OFF1-OFFN respectively generate the bits PTR[1]-PTR[N] of the pointer signal PTR.

The D-type flip-flops OFF1-OFFN temporarily store the preceding pointer signal PPTR according to the sample clock pulse TS and provides the preceding pointer signal PPTR as the pointer signal PTR after delaying for one cycle of the sample clock pulse TS.

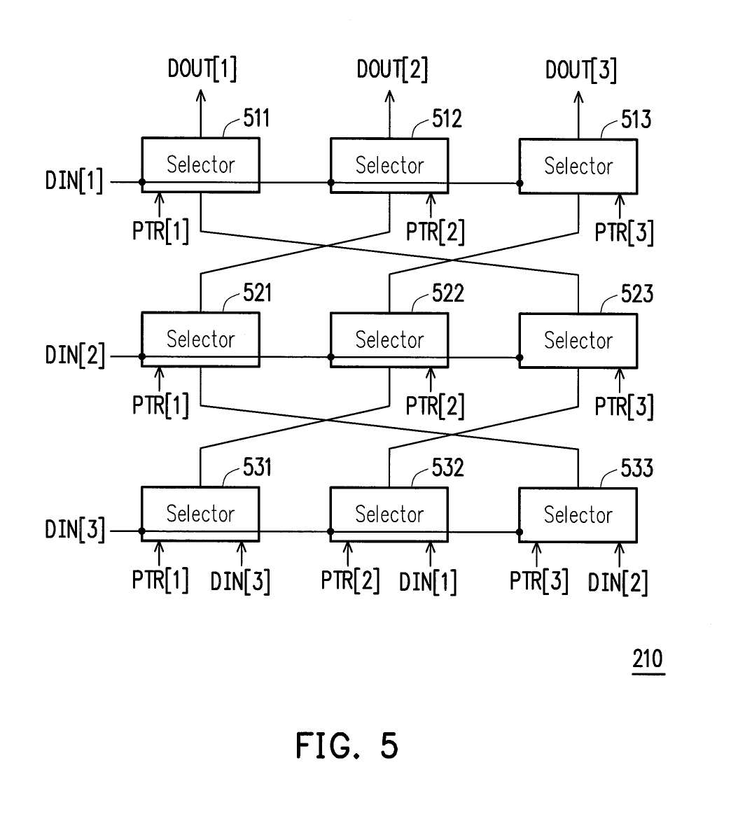

FIG. 5 is a diagram illustrating an implementation of the data aligner 210 according to an embodiment of the invention. Referring to FIG. 5, the data aligner 210 includes a plurality of selectors 511-533. The selectors 511, 521, and 531 in the first column respectively receive the input bits DIN[1], DIN[2], and DIN[3] of the input matching data DIN. The selectors 511, 521, and 531 also respectively receive the outputs of the selectors 523 and 533 and the input bit DIN[3]. Besides, the selectors 511, 521, and 531 further receive the first bit PTR[1] of the pointer signal PTR. The selectors 512, 522, and 532 in the second column respectively receive the input bits DIN[1], DIN[2], and DIN[3] of the input matching data DIN. The selectors 512, 522, and 532 also respectively receive the outputs of the selectors 521 and 531 and the input bit DIN[1]. Besides, the selectors 512, 522, and 532 further receive the second bit PTR[2] of the pointer signal PTR. The selectors 513, 523, and 533 in the third column respectively receive the input bits DIN[1], DIN[2], and DIN[3] of the input matching data DIN. The selectors 513, 523, and 533 also respectively receive the outputs of the selectors 522 and 532 and the input bit DIN[2]. Besides, the selectors 513, 523, and 533 further receive the third bit PTR[3] of the pointer signal PTR.

When the bits PTR[1]-PTR[3] of the pointer signal PTR respectively received by the selectors 511-533 are enabled (for example, assigned with the logic value 1), the selectors respectively receiving the bits PTR[1]-PTR[3] (which have the logic value 1) of the pointer signal PTR output the input bits DIN[1], DIN[2] which are horizontally input, and DIN[3] (as shown in FIG. 5). Contrarily, the selectors respectively receiving the bits PTR[1]-PTR[3] (which have the logic value 0) of the pointer signal PTR output the signals which are vertically input into the selectors (as shown in FIG. 5).

Assuming that the input bits DIN[1], DIN[2], and DIN[3] respectively have the logic values 0, 1, and 1, when the second bit PTR[2] of the pointer signal PTR has the logic value 1 and the other bits of the pointer signal PTR have the logic value 0, the selector 532 receives the bit PTR[2] of the pointer signal PTR (which has the logic value 1) and sends the input bit DIN[3] (which has the logic value 1) to the selector 523. The selector 523 sends the input bit DIN[3] received by the selector 532 to the selector 511, and the selector 511 outputs the received input bit DIN[3] as an output bit DOUT[1]. Similarly, the selector 522 receives the bit PTR[2] (which has the logic value 1) of the pointer signal PTR and sends the input bit DIN[2] (which has the logic value 1) to the selector 513. The selector 513 outputs the received input bit DIN[2] as an output bit DOUT[3]. Additionally, the selector 512 receives the bit PTR[2] (which has the logic value 1) of the pointer signal PTR, and the selectors 512 and sends the input bit DIN[1] (which has the logic value 0) as an output bit DOUT[2]. Namely, the output bits DOUT[1]-DOUT[3] respectively have the logic values 1, 0, and 1.

However, the data aligner 210 composed of 3×3 selectors illustrated in FIG. 5 is only an example. A designer can adjust the number of the selectors according to the actual design requirement.

It should be mentioned herein that in the present embodiment, at most one of the bits PTR[1]-PTR[3] of the pointer signal PTR can have the logic value 1.

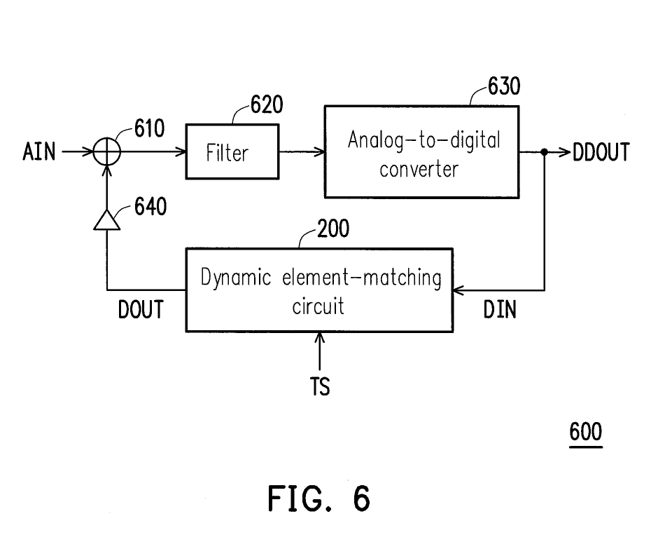

FIG. 6 is a diagram of a delta-sigma modulation apparatus 600 according to an embodiment of the invention. Referring to FIG. 6, the delta-sigma modulation apparatus 600 includes an arithmetic unit 610, a filter 620, an analog-to-digital converter (ADC) 630, a dynamic element-matching circuit 200, and a digital-to-analog converter (DAC) 640. The arithmetic unit 610 receives an input data AIN and the output data of the DAC 640 and performs an arithmetic operation on the same to generate an operation result. The filter 620 is coupled to the arithmetic unit 610 and filters the operation result. The ADC 630 performs an analog-to-digital conversion operation on the filtered operation result to generate a digital output data DDOUT. The dynamic element-matching circuit 200 is coupled to the ADC 630 and the DAC 640. The DAC 640 converts the output of the dynamic element-matching circuit 200 into an analog signal and sends the analog signal to the arithmetic unit 610. The dynamic element-matching circuit 200 converts the output data DDOUT into the input matching data DIN and generates the output matching data DOUT according to the input matching data DIN and the sample clock pulse TS.

The delta-sigma modulation apparatus 600 further includes the DAC 640. The DAC 640 is serially connected on the path of the dynamic element-matching circuit 200 for sending the output matching data DOUT to the arithmetic unit 610.

Please note that the dynamic element-matching circuit 200 in the present embodiment is exactly the same as the dynamic element-matching circuit 200 illustrated in FIG. 2. The operation details of the dynamic element-matching circuit 200 have been described in detail in the embodiment illustrated in FIG. 2 therefore will not be described herein.

As described above, the invention provides a dynamic element-matching circuit without any adder, such that the time for transmitting an input matching data to a logic operation circuit is shortened. Besides, since no adder is required, the circuit area and the hardware cost of the dynamic element-matching circuit are effectively reduced, and the power consumption when the dynamic element-matching circuit is in operation is also effectively reduced.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A dynamic element-matching circuit, adapted to a delta-sigma modulation apparatus, the dynamic element-matching circuit comprising:
a data aligner, receiving an input matching data and a pointer signal, and shifting the input matching data according to the pointer signal to generate an output matching data;
a logic operation circuit, coupled to the data aligner, receiving the output matching data, and performing a logic operation on the output matching data to generate a preceding pointer signal; and
a delayer, coupled to the logic operation circuit and the data aligner, receiving the preceding pointer signal, and delaying the preceding pointer signal according to a sample clock pulse to generate the pointer signal.

2. The dynamic element-matching circuit according to claim 1, wherein the logic operation circuit comprises:
AND gates, wherein an input of the 1^{st} AND gate receives values of a 1^{st} output bit and an N^{th} output bit among output bits of the output matching data, an output of the 1^{st} AND gate generates a 1^{st} bit of the preceding pointer signal, an input of the i^{th} AND gate receives reverse value of the i^{th} output bit and the (i+1)^{th} output bit among the output bits of the output matching data, and an output of the i^{th} AND gate generates an i^{th} bit of the preceding pointer signal, wherein N is a positive integer greater than 1, and i is a positive integer greater than 1 and smaller than N.

3. The dynamic element-matching circuit according to claim 1, wherein the logic operation circuit comprises:
N NAND gates, wherein an input of the 1^{st} NAND gate receives reverse value of a 1^{st} output bit and an N^{th} output bit among output bits of the output matching data, and an input of the i^{th} NAND gate receives reverse value of the i^{th} output bit and the (i+1)^{th} output bit among the output bits of the output matching data; and
N NOT gates, wherein inputs of the NOT gates are respectively coupled to outputs of the NAND gates, and outputs of the NOT gates generate the preceding pointer signal, wherein N is a positive integer greater than 1, and i is a positive integer greater than 1 and smaller than N.

4. The dynamic element-matching circuit according to claim 1, wherein the data aligner is a lookup table, and the lookup table records a corresponding relationship among the input matching data, the pointer signal, and the output matching data.

5. The dynamic element-matching circuit according to claim 1, wherein the delayer is a latch, and the latch latches the preceding pointer signal according to the sample clock pulse and provides the latched preceding pointer signal as the pointer signal according to the sample clock pulse.

6. A delta-sigma modulation apparatus, comprising:
an arithmetic unit, receiving an input data and an output matching data, and performing an arithmetic operation on the input data and the output matching data to generate an operation result;
an analog-to-digital converter (ADC), coupled to the arithmetic unit, receiving the operation result, and performing an analog-to-digital conversion operation on the operation result to generate an output data;
a filter, receiving the operation result, and amplifying and filtering the operation result;
a dynamic element-matching circuit, coupled to the ADC, and converting the output data into a digital input matching data, wherein the dynamic element-matching circuit comprises:
a data aligner, receiving the input matching data and a pointer signal, and shifting the input matching data according to the pointer signal to generate the output matching data;
a logic operation circuit, coupled to the data aligner, receiving the output matching data, and performing a logic operation on the output matching data to generate a preceding pointer signal; and
a delayer, coupled to the logic operation circuit and the data aligner, receiving the preceding pointer signal, and delaying the preceding pointer signal according to a sample clock pulse to generate the pointer signal; and
a digital-to-analog converter (DAC), receiving a data output by the dynamic element-matching circuit, and performing a digital-to-analog conversion operation on the data to generate the output matching data.

7. The delta-sigma modulation apparatus according to claim 6, wherein the logic operation circuit comprises:
N AND gates, wherein an input of the 1^{st} AND gate receives values of a 1^{st} output bit and an N^{th} output bit among output bits of the output matching data, an output of the 1^{st} AND gate generates a 1^{st} bit of the preceding pointer signal, an input of the i^{th} AND gate receives reverse value of the i^{th} output bit and the (i+1)^{th} output bit among the output bits of the output matching data, and an output of the i^{th} AND gate generates an i^{th} bit of the preceding pointer signal.

8. The delta-sigma modulation apparatus according to claim 6, wherein the logic operation circuit comprises:
N NAND gates, wherein an input of the 1^{st} NAND gate receives reverse value of a 1^{st} output bit and an N^{th} output bit among output bits of the output matching data, and an input of the i^{th} NAND gate receives reverse value of the i^{th} output bit and the (i+1)^{th} output bit among the output bits of the output matching data; and
N NOT gates, wherein inputs of the NOT gates are respectively coupled to outputs of the NAND gates, and outputs of the NOT gates generate the preceding pointer signal.

9. The delta-sigma modulation apparatus according to claim 6, wherein the data aligner is a lookup table, and the lookup table records a corresponding relationship among the input matching data, the pointer signal, and the output matching data.

10. The delta-sigma modulation apparatus according to claim 6, wherein the delayer is a latch, and the latch latches the preceding pointer signal according to the sample clock pulse and provides the latched preceding pointer signal as the pointer signal according to the sample clock pulse.
